(19) United States
(12) Patent Application Publication
(10) Pub. No.: US 2026/0191085 A1
(43) Pub. Date: Jul. 2, 2026

(54) METHOD FOR PRODUCING SEMICONDUCTOR DEVICE, SEMICONDUCTOR DEVICE, METHOD FOR PRODUCING INTEGRATED CIRCUIT ELEMENT, AND INTEGRATED CIRCUIT ELEMENT

(71) Applicant: Resonac Corporation, Minato-ku, Tokyo (JP)

(72) Inventors: Tadashi OKUDA, Minato-ku, Tokyo (JP); Toshiaki SHIRASAKA, Minato-ku, Tokyo (JP); Shizu FUKUZUMI, Minato-ku, Tokyo (JP); Tomoaki SHIBATA, Minato-ku, Tokyo (JP); Kazuyuki MITSUKURA, Minato-ku, Tokyo (JP)

(21) Appl. No.: 18/857,457

(22) PCT Filed: Jul. 1, 2022
(86) PCT No.: PCT/JP2022/026493

§ 371 Date: Oct. 17, 2024

(51) Int. Cl. H10W 74/10; H10P 58/00; H10W 74/01; H10W 74/47; H10W 80/00; H10W 90/00; H10W 90/26

(52) U.S. Cl. CPC H10W 74/137; H10P 58/20; H10W 74/01; H10W 90/26; H10W 90/792; H10W 74/47; H10W 80/334

(57) ABSTRACT

A method for producing a semiconductor device is disclosed. A method for producing a semiconductor device includes preparing a multilayer body including a semiconductor base material, an electrode disposed on a main surface of the semiconductor base material, and an organic insulating film disposed on the main surface and containing a resin material that exhibits curability; curing the organic insulating film; cutting the multilayer body along a planned cutting line to acquire at least one integrated circuit element; and bonding the acquired integrated circuit element to another integrated circuit element. The method for producing the semiconductor device includes removing at least a part of the planned cutting portion corresponding to the planned cutting line in the organic insulating film before the curing of the organic insulating film.

### TECHNICAL FIELD

The present disclosure relates to a method for producing a semiconductor device, a semiconductor device, an integrated circuit element, and a method for producing an integrated circuit element.

### BACKGROUND ART

Patent Literature 1 discloses an example of a hybrid bonding method which is a three-dimensional integration technique of a semiconductor. In the hybrid bonding method, an organic insulating film is formed at the periphery of an electrode on each bonding surface of a pair of integrated circuit elements, and the electrode and the electrode are bonded, and the insulating film and the insulating film are bonded. Similar techniques are disclosed in Patent Literatures 2 and 3.

### CITATION LIST

### Patent Literature

Patent Literature 1: US 2019/0157333 A

Patent Literature 2: Japanese Unexamined Patent Publication No. 2012-069585

Patent Literature 3: WO 2020/085183 A

### SUMMARY OF INVENTION

### Technical Problem

The integrated circuit element to be bonded by the above-described hybrid bonding method is acquired, for example, by preparing a multilayer body including an electrode and an organic insulating film disposed on a semiconductor base material, curing the organic insulating film, and then dividing the multilayer body. When the organic insulating film is cured, the organic insulating film may be contracted thus causing warpage in the multilayer body. When warpage occurs in the multilayer body, warpage also remains in integrated circuit elements acquired by dividing the multilayer body, and there is a risk that a bonding failure may occur when the integrated circuit elements are bonded to each other.

An object of the present disclosure is to provide a method for producing a semiconductor device, a semiconductor device, a method for producing an integrated circuit element, and an integrated circuit element capable of suppressing occurrence of a bonding failure between integrated circuit elements.

### Solution to Problem

The present disclosure relates to, as one aspect, a method for producing a semiconductor device. A method for producing a semiconductor device includes preparing a multilayer body including a semiconductor base material, an electrode disposed on a main surface of the semiconductor base material, and an organic insulating film disposed on the main surface and containing a resin material that exhibits curability; curing the organic insulating film; cutting the multilayer body along a planned cutting line to acquire at least one integrated circuit element; and bonding the acquired integrated circuit element to another integrated circuit element. The method for producing the semiconductor device includes removing at least a part of the planned cutting portion corresponding to the planned cutting line in the organic insulating film before the curing of the organic insulating film.

In this production method, at least a part of the planned cutting portion corresponding to the planned cutting line in the organic insulating film is removed before the curing of the organic insulating film. In this case, since the volume of the organic insulating film is reduced by removing a part of the planned cutting portion, it is possible to reduce warpage of the multilayer body due to curing shrinkage that occurs when the organic insulating film is cured. Therefore, warpage of the integrated circuit element acquired by cutting the multilayer body can be reduced. Furthermore, the planned cutting portion is located at an end portion of the cut and divided integrated circuit element. Therefore, even when, for example, a recess is formed at the end portion of the integrated circuit element by removing the planned cutting portion, the influence on the bonding between the integrated circuit elements can be suppressed small as compared with the case where the recess is formed at, for example, the center of the integrated circuit element. Furthermore, even when the burr is generated at the time of cutting the multilayer body, the burr is located in the space generated by removing a part of the planned cutting portion, so that the burr can be suppressed from protruding out from the bonding surface of the integrated circuit element. Therefore, according to the method for producing the semiconductor device, the occurrence of a bonding failure between the integrated circuit elements can be suppressed.

In the above-described method for producing the semiconductor device, the removing of at least a part of the planned cutting portion may include forming a groove in the organic insulating film along the planned cutting line. In this case, the planned cutting portion can be removed more reliably.

In the above-described method for producing the semiconductor device, the depth of the groove may be greater than or equal to 20% of the thickness of the organic insulating film. In this case, the volume of the organic insulating film can be further reduced, and the warpage of the multilayer body due to the curing shrinkage that occurs when the organic insulating film is cured can be further reduced. As a result, the warpage of the integrated circuit element acquired by cutting the multilayer body is reduced, and the occurrence of bonding failure between the integrated circuit elements can be further suppressed.

In the above-described method for producing the semiconductor device, wherein an aspect ratio of a width with respect to a depth of the groove may be 15:20 to 0.8:300. In this case, the groove having an appropriate size can be formed in the organic insulating film.

In the above-described method for producing the semiconductor device, the groove may include a first groove and a second groove adjacent to each other, and a pitch between the first groove and the second groove may be less than or equal to 40 mm. In this case, since many grooves are formed in the organic insulating film, the volume of the organic insulating film can be further reduced, and the warpage of the multilayer body due to the curing shrinkage that occurs when the organic insulating film is cured can be further reduced. As a result, the warpage of the integrated circuit element acquired by cutting the multilayer body is reduced, and the occurrence of bonding failure between the integrated circuit elements can be further suppressed.

In the above-described method for producing the semiconductor device, the resin material has photosensitivity, and the removing of at least a part of the planned cutting portion may include removing a part of the planned cutting portion by performing exposure and development on the organic insulating film. In this case, it is possible to easily remove at least a part of the planned cutting portion while maintaining the flatness of the surface of the organic insulating film. It is also possible to remove the fine planned cutting portion.

Furthermore, the method for producing the semiconductor device may further include pre-baking and semi-curing the organic insulating film before the removing of at least a part of the planned cutting portion. In this case, at least a part of the planned cutting portion (e.g., formation of a groove etc.) can be accurately removed in a state where the organic insulating film is semi-cured.

In the above-described method for producing the semiconductor device, the removing of at least a part of the planned cutting portion may include thinning or removing the entire planned cutting portion. In this case, the volume of the organic insulating film can be further reduced, and the warpage of the multilayer body due to the curing shrinkage that occurs when the organic insulating film is cured can be further reduced. As a result, the warpage of the integrated circuit element acquired by cutting the multilayer body is reduced, and the occurrence of bonding failure between the integrated circuit elements can be further suppressed.

In the above-described method for producing the semiconductor device, the acquiring of the integrated circuit element may include cutting the multilayer body by a dicing blade. Although the burr may be generated when the multilayer body is cut by the dicing blade, the burr can be suppressed from protruding out from the bonding surface of the integrated circuit element for the reason described above. Therefore, the occurrence of a bonding failure between the integrated circuit elements can be suppressed.

The present disclosure relates to, as another aspect, a semiconductor device. The semiconductor device includes an integrated circuit element and another integrated circuit element bonded to the integrated circuit element. The integrated circuit element includes a semiconductor substrate, and an electrode and an organic insulating film disposed on a main surface of the semiconductor substrate. The thickness of the outer edge portion of the organic insulating film is thinner than the thickness of the other portion of the organic insulating film, or the organic insulating film is not disposed on the outer edge portion of the semiconductor substrate.

In the above-described semiconductor device, the thickness of the outer edge portion of the organic insulating film included in the integrated circuit element is thinner than the thickness of the other portion of the organic insulating film, or the organic insulating film is not disposed on the outer edge portion of the semiconductor substrate. In this case, in the process of producing the semiconductor device, the volume of the organic insulating film before being cut can be reduced, and the multilayer body having the organic insulating film can be suppressed from being warped due to curing shrinkage when the organic insulating film is cured. This can reduce the warpage of the integrated circuit element. Furthermore, in the above-described semiconductor device, a portion where the thickness of the organic insulating film is thin or the organic insulating film is not disposed is an end portion of the integrated circuit element. Therefore, it is possible to suppress the influence on the bonding between the integrated circuit elements due to the decrease in the thickness of the organic insulating film or the absence of the organic insulating film. Furthermore, in the above-described semiconductor device, even when a burr is generated in the outer edge portion of the organic insulating film or the outer edge portion of the semiconductor substrate, the burr can be suppressed from protruding out from the bonding surface of the integrated circuit element. Therefore, according to the semiconductor device, the occurrence of a bonding failure between the integrated circuit elements can be suppressed.

In the above-described semiconductor device, a burr may be formed in an outer edge portion of the organic insulating film or an outer edge portion of the semiconductor substrate. Even when the burr is generated in the outer edge portion of the organic insulating film or the outer edge portion of the semiconductor substrate, the burr can be suppressed from protruding out from the bonding surface of the integrated circuit element for the above reason, and the occurrence of bonding failure between the integrated circuit elements can be suppressed.

The present disclosure relates to, as still another aspect, a method for producing an integrated circuit element. The method for producing the integrated circuit element includes preparing a multilayer body including a semiconductor base material, an electrode disposed on a main surface of the semiconductor base material, and an organic insulating film disposed on the main surface and containing a resin material that exhibits curability; curing the organic insulating film; and cutting the multilayer body along a planned cutting line to acquire an integrated circuit element. The method for producing the integrated circuit element includes removing at least a part of a planned cutting portion corresponding to the planned cutting line in the organic insulating film before the curing of the organic insulating film.

The above-described method for producing the integrated circuit element includes removing at least a part of a planned cutting portion corresponding to the planned cutting line in the organic insulating film before the curing of the organic insulating film. In this case, similarly to the method for producing the semiconductor device, the occurrence of the bonding failure between the integrated circuit elements can be suppressed.

The present disclosure relates to, as still another aspect, an integrated circuit element. The integrated circuit element includes a semiconductor substrate, and an electrode and an organic insulating film disposed on a main surface of the semiconductor substrate. The thickness of the outer edge portion of the organic insulating film is thinner than the thickness of the other portion of the organic insulating film, or the organic insulating film is not disposed on the outer edge portion of the semiconductor substrate.

In the above-described integrated circuit element, the thickness of the outer edge portion of the organic insulating film is thinner than the thickness of the other portion of the organic insulating film, or the organic insulating film is not disposed on the outer edge portion of the semiconductor substrate. In this case, similarly to the semiconductor device, the occurrence of the bonding failure between the integrated circuit elements can be suppressed.

### Advantageous Effects of Invention

According to one aspect of the present disclosure, it is possible to suppress the occurrence of a bonding failure between integrated circuit elements.

### BRIEF DESCRIPTION OF DRAWINGS

FIG. 1 is a cross-sectional view schematically illustrating an example of a semiconductor device produced by a production method according to the present embodiment.

FIG. 2 is a plan view of an integrated circuit element included in a semiconductor device.

FIG. 3 is a plan view of a multilayer body.

FIG. 4 is a cross-sectional view illustrating a method for producing an integrated circuit element.

FIG. 5 is a cross-sectional view illustrating the method for producing the integrated circuit element.

FIG. 6 is a cross-sectional view illustrating the method for producing the integrated circuit element.

FIG. 7 is a cross-sectional view illustrating the method for producing the integrated circuit element.

FIG. 8 is a view showing a measurement result of warpage of a multilayer body.

FIG. 9 is a view illustrating an example of a multilayer body in which warpage has occurred.

FIG. 10 is a view illustrating another example of a multilayer body in which warpage has occurred.

FIG. 11 is a photograph of a burr formed in an integrated circuit element according to a third example.

FIG. 12 is a photograph of a burr formed in an integrated circuit element according to a second comparative example.

FIG. 13 is a cross-sectional view schematically illustrating a semiconductor device according to a modified example.

### DESCRIPTION OF EMBODIMENTS

Hereinafter, some embodiments of the present disclosure will be described in detail with reference to the drawings as necessary. In the following description, the same or corresponding portions are denoted by the same reference numerals, and redundant description will be omitted. Furthermore, unless otherwise specified, the positional relationship such as up, down, left, and right is based on the positional relationship illustrated in the drawings. Furthermore, the dimensional ratios in the drawings are not limited to the illustrated ratios.

In the present specification, the numerical range indicated using “to” includes the numerical values described before and after “to” as the minimum value and the maximum value, respectively. In the numerical ranges described in stages in the present specification, the upper limit value or the lower limit value described in one numerical range may be replaced with the upper limit value or the lower limit value of the numerical range described in other stages. In addition, in the numerical range described in the present specification, the upper limit value or the lower limit value of the numerical range may be replaced with a value shown in the examples.

### (Configuration of Semiconductor Device)

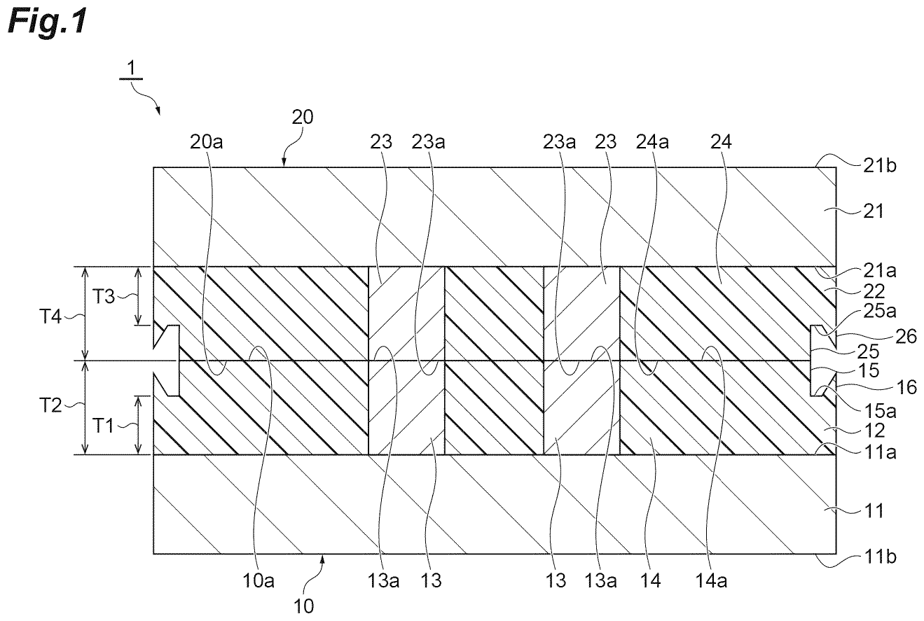

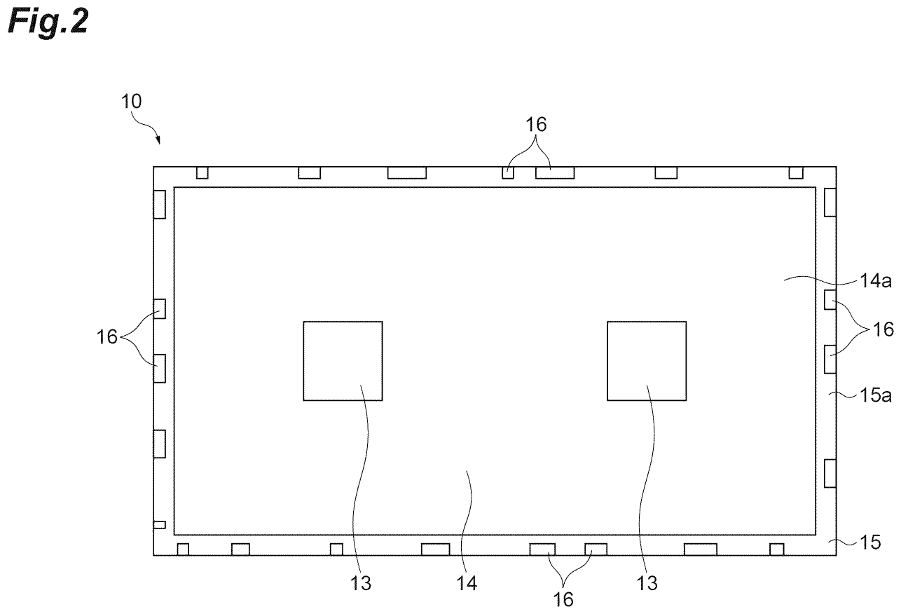

FIG. 1 is a cross-sectional view schematically illustrating an example of a semiconductor device produced by a production method according to the present embodiment. FIG. 2 is a plan view of an integrated circuit element included in a semiconductor device. As illustrated in FIGS. 1 and 2, the semiconductor device 1 includes an integrated circuit element 10 and an integrated circuit element 20 bonded to the integrated circuit element 10. The integrated circuit element 20 includes a semiconductor substrate 21 and a wiring layer 22 disposed on the semiconductor substrate 21. In the present embodiment, the integrated circuit element 10 and the integrated circuit element 20 have similar configurations to each other. The integrated circuit element 10 includes a semiconductor substrate 11 and a wiring layer 12 disposed on the semiconductor substrate 11.

The semiconductor substrate 11 includes, for example, a semiconductor element (not illustrated) constituting a functional circuit corresponding to a semiconductor chip such as a large scale integrated circuit (LSI) chip or a complementary metal oxide semiconductor (CMOS) sensor. The semiconductor substrate 11 has a main surface 11a and a main surface 11b opposing the main surface 11a, and is configured to have the above-described plurality of semiconductor elements on the main surface 11b or inside the semiconductor substrate 11. The semiconductor substrate 11 is formed of, for example, SiO₂. In the present embodiment, the semiconductor substrate 11 is formed in a rectangular plate shape.

The wiring layer 12 includes a plurality of electrodes 13 and an organic insulating film 14. The electrode 13 is disposed on the main surface 11a of the semiconductor substrate 11, and is electrically connected to a semiconductor element provided on the semiconductor substrate 11. The electrode 13 penetrates the organic insulating film 14 in the thickness direction of the semiconductor substrate 11. As a result, the surface 13a of the electrode 13 on the side opposite to the semiconductor substrate 11 is exposed from the organic insulating film 14. The diameter of the electrode 13 may be, for example, greater than or equal to 0.005 μm and less than or equal to 20 μm. The electrode 13 is formed of, for example, a conductive metal such as copper (Cu).

The organic insulating film 14 is disposed on the main surface 11a of the semiconductor substrate 11 so as to cover the side surface of the electrode 13. The organic insulating film 14 is formed of, for example, an organic insulating material. The organic insulating material may be a polyimide, a polyimide precursor (e.g., a polyimide amic ester or a polyamic acid), a polyamideimide, benzocyclobutene (BCB), polybenzoxazole (PBO), or a PBO precursor. The organic insulating material contained in the organic insulating film 14 may contain a photosensitive resin or a thermosetting resin. The organic insulating material contained in the organic insulating film 14 has a lower elastic modulus than an inorganic material such as silicon oxide (SiO₂). The elastic modulus of the organic insulating material is, for example, less than or equal to 7.0 GPa, and preferably less than or equal to 5.0 GPa or 3.0 GPa. The elastic modulus here means Young's modulus.

In the organic insulating film 14, a recess 15 recessed from a surface 14a of the organic insulating film 14 on the side opposite to the semiconductor substrate 11 toward the semiconductor substrate 11 is formed. As illustrated in FIG. 2, the recess 15 is formed in an outer edge portion of the organic insulating film 14. In the present embodiment, the recess 15 is formed in a continuous rectangular annular shape along the outer edge portion of the organic insulating film 14. The recess 15 is formed at a position different from the arrangement place of the electrode 13 in the organic insulating film 14, and is spaced apart from the electrode 13. As a result, the electrode 13 is not exposed in the recess 15.

The bottom surface 15a of the recess 15 is spaced apart from the semiconductor substrate 11. As a result, the main surface 11a of the semiconductor substrate 11 is not exposed in the bottom surface 15a of the recess 15. Since the recess 15 is formed, the thickness T1 of the outer edge portion (the portion where the recess 15 is formed) of the organic insulating film 14 is thinner than the thickness T2 of the other portion (the portion on the inner side than the recess 15) of the organic insulating film 14. Here, the thickness T1 of the outer edge portion of the organic insulating film 14 is a thickness of a portion where a burr 16 to be described later is not formed.

The recess 15 may be formed by, for example, a photolithography process (exposure and development). In this case, the organic insulating film 14 is formed to include a photosensitive resin material. Instead of the photolithography process, the recess 15 may be formed by imprinting or the like.

A burr 16 is formed at an outer edge portion of the organic insulating film 14. For example, the burr 16 protrudes out from the bottom surface 15a of the recess 15. In the present embodiment, as illustrated in FIG. 2, the burr 16 is discontinuously (partially) formed on all sides of the organic insulating film 14, but may be formed only on some sides of the organic insulating film 14, or may be continuously formed over all sides of the organic insulating film 14. In the present embodiment, the burr 16 protrudes out in a direction substantially perpendicular to the bottom surface 15a and has a shape tapered toward the distal end. When viewed from a direction perpendicular to the thickness direction of the semiconductor substrate 11, the protruding height of the burr 16 is lower than the surface 14a of the organic insulating film 14, whereby the burr 16 is located in the recess 15. The burr 16 is formed in an outer edge portion of the organic insulating film 14 when the integrated circuit element 10 is cut out from the wafer or the like using, for example, a dicing blade or the like.

The integrated circuit element 20 includes a semiconductor substrate 21 and a wiring layer 22 disposed on the semiconductor substrate 21. Similarly to the semiconductor substrate 11, the semiconductor substrate 21 includes, for example, a semiconductor element (not illustrated) constituting a functional circuit corresponding to a semiconductor chip such as a large scale integrated circuit (LSI) chip or a complementary metal oxide semiconductor (CMOS) sensor. The semiconductor substrate 21 has a main surface 21a and a main surface 21b opposing the main surface 21a, and is configured to have the above-described semiconductor element on the main surface 21b or inside the semiconductor substrate 21. The semiconductor substrate 21 is formed of, for example, SiO₂. In the present embodiment, the semiconductor substrate 21 is formed in a rectangular plate shape.

The wiring layer 22 includes a plurality of electrodes 23 and an organic insulating film 24. The electrode 23 is disposed on the main surface 21a of the semiconductor substrate 21, and is electrically connected to a semiconductor element provided on the semiconductor substrate 21. The electrode 23 penetrates the organic insulating film 24 in the thickness direction of the semiconductor substrate 21. As a result, the surface 23a of the electrode 23 on the side opposite to the semiconductor substrate 21 is exposed from the organic insulating film 24. The diameter of the electrode 23 may be, for example, greater than or equal to 0.005 μm and less than or equal to 20 μm. The electrode 23 is formed of, for example, a conductive metal such as copper (Cu).

The organic insulating film 24 is disposed on the main surface 21a of the semiconductor substrate 21 so as to cover the side surface of the electrode 23. The organic insulating film 24 is formed of, for example, an organic insulating material. The organic insulating material may be a polyimide, a polyimide precursor (e.g., a polyimide amic ester or a polyamic acid), a polyamideimide, benzocyclobutene (BCB), polybenzoxazole (PBO), or a PBO precursor. The organic insulating material contained in the organic insulating film 24 may contain a photosensitive resin or a thermosetting resin. The organic insulating material contained in the organic insulating film 24 has a lower elastic modulus than an inorganic material such as silicon oxide (SiO₂). The elastic modulus of the organic insulating material is, for example, less than or equal to 7.0 GPa, and preferably less than or equal to 5.0 GPa or 3.0 GPa. The elastic modulus here means Young's modulus.

In the organic insulating film 24, a recess 25 recessed from a surface 24a of the organic insulating film 24 on the side opposite to the semiconductor substrate 21 toward the semiconductor substrate 21 is formed. The recess 25 is formed in an outer edge portion of the organic insulating film 24. In the present embodiment, similarly to the recess 15, the recess 25 is formed in a continuous rectangular annular shape along the outer edge portion of the organic insulating film 24. The recess 25 is formed at a position different from the arrangement place of the electrode 23 in the organic insulating film 24, and is spaced apart from the electrode 23. As a result, the electrode 23 is not exposed in the recess 25.

The bottom surface 25a of the recess 25 is spaced apart from the semiconductor substrate 21. As a result, the main surface 21a of the semiconductor substrate 21 is not exposed in the bottom surface 25a of the recess 25. Since the recess 25 is formed, the thickness T3 of the outer edge portion (the portion where the recess 25 is formed) of the organic insulating film 24 is thinner than the thickness T4 of the other portion (the portion on the inner side than the recess 25) of the organic insulating film 24. Here, the thickness T3 of the outer edge portion of the organic insulating film 24 is a thickness of a portion where a burr 26 to be described later is not formed.

The recess 25 may be formed by, for example, a photolithography process (exposure and development). In this case, the organic insulating film 24 is formed to include a photosensitive resin material. Instead of the photolithography process, the recess 25 may be formed by imprinting or the like.

A burr 26 is formed at an outer edge portion of the organic insulating film 24. For example, the burr 26 protrudes out from the bottom surface 25a of the recess 25. In the present embodiment, similarly to the burr 16, the burr 26 is discontinuously (partially) formed on all sides of the organic insulating film 24, but may be formed only on some sides of the organic insulating film 24, or may be continuously formed over all sides of the organic insulating film 24. In the present embodiment, the burr 26 protrudes out in a direction substantially perpendicular to the bottom surface 25a and has a shape tapered toward the distal end. When viewed from a direction perpendicular to the thickness direction of the semiconductor substrate 21, the protruding height of the burr 26 is lower than the surface 24a of the organic insulating film 24, whereby the burr 26 is located in the recess 25. The burr 26 is formed in an outer edge portion of the organic insulating film 24 when the integrated circuit element 20 is cut out from the wafer or the like using, for example, a dicing blade or the like.

In the semiconductor device 1, the wiring layer 12 of the integrated circuit element 10 and the wiring layer 22 of the integrated circuit element 20 are bonded to each other via the bonding surface 10a and the bonding surface 20a. The bonding surface 10a is constituted by the surface 13a of the electrode 13 and the surface 14a of the organic insulating film 14. The bonding surface 20a is constituted by the surface 23a of the electrode 23 and the surface 24a of the organic insulating film 24. In the semiconductor device 1, the electrode 13 is bonded to the electrode 23, and the organic insulating film 14 is bonded to the organic insulating film 24. The burr 16 formed on the organic insulating film 14 is separated from the burr 26 formed on the organic insulating film 24 and is not in contact.

### (Method for Producing Semiconductor Device)

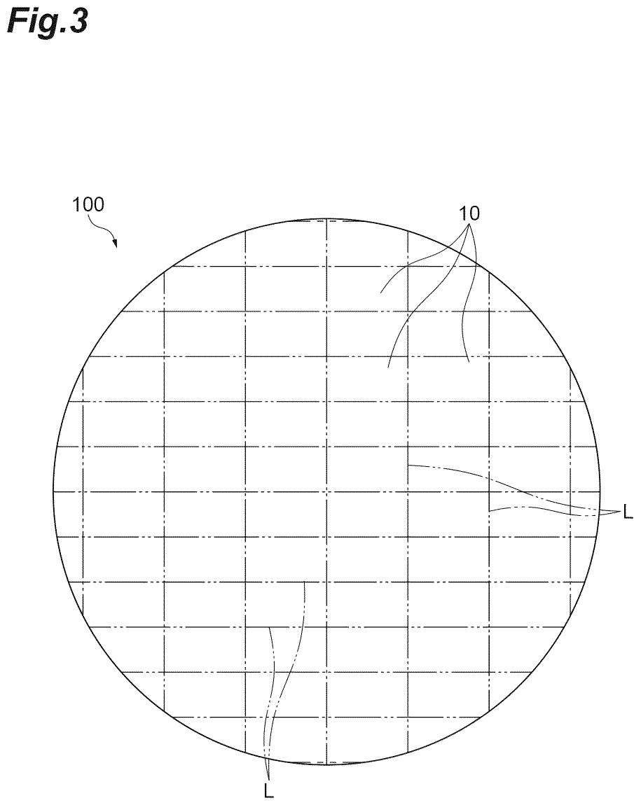

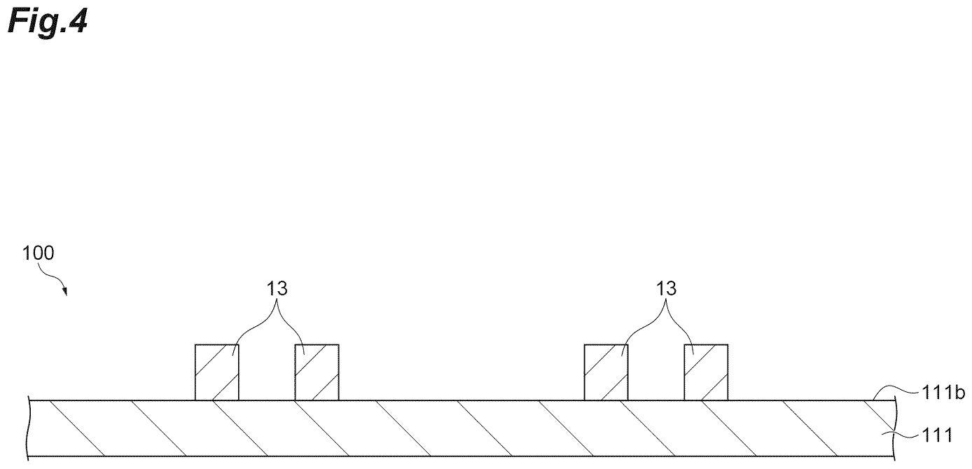

Next, a method for producing the semiconductor device 1 will be described with reference to FIGS. 3 to 7. FIG. 3 is a plan view of the multilayer body. FIGS. 4 to 7 are cross-sectional views illustrating a method for producing an integrated circuit element used in producing a semiconductor device.

The semiconductor device 1 can be produced, for example, through the following steps (a) to (f).
(a) Step of preparing a multilayer body 100 including a semiconductor base material 111, a plurality of electrodes 13, and an organic insulating film 114 containing a resin material that exhibits curability.
(b) Step of pre-baking and semi-curing the organic insulating film 114.
(c) Step of removing at least a part of a planned cutting portion 117 corresponding to a planned cutting line L in the organic insulating film 114.
(d) Step of curing the organic insulating film 114.
(e) Step of cutting the multilayer body 100 to acquire at least one integrated circuit element 10.
(f) Step of bonding the integrated circuit element 10 and the integrated circuit element 20.
   [Step (a)]

Step (a) is a step of preparing a multilayer body 100 including semiconductor base material 111, a plurality of electrodes 13 disposed on a main surface 111a of semiconductor base material 111, and an organic insulating film 114 disposed on the main surface 111a and containing a resin material that exhibits curability. The resin material used here is an uncured resin material. The multilayer body 100 may be prepared as, for example, a circular plate-shaped semiconductor wafer as illustrated in FIG. 3. In step (a), as illustrated in FIG. 4, first, the semiconductor base material 111 in which the plurality of electrodes 13 are disposed on the main surface 111a is prepared. The semiconductor base material 111 is provided with a plurality of semiconductor elements (not illustrated) constituting a functional circuit. The semiconductor base material 111 has a plurality of portions that become the semiconductor substrate 11 of the integrated circuit element 10 after the step of cutting the multilayer body 100 described later.

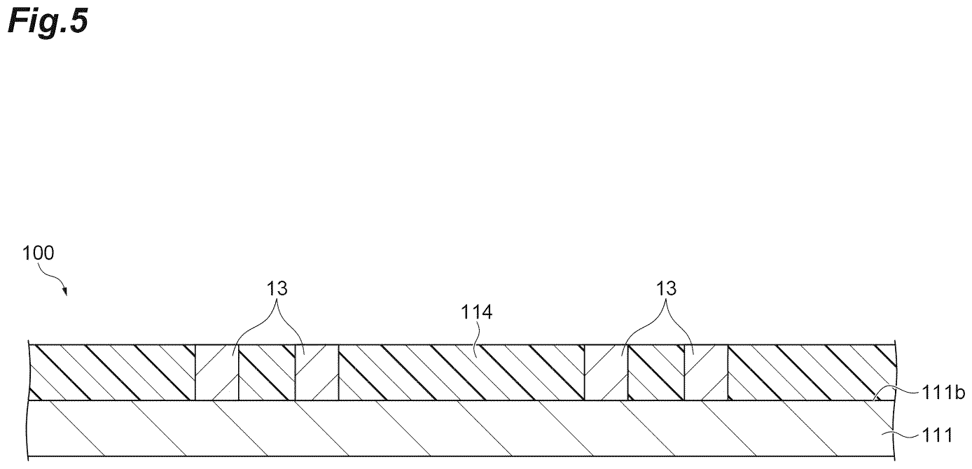

Subsequently, as illustrated in FIG. 5, an uncured resin material for forming the organic insulating film 114 is applied onto the main surface 111a and spread on the semiconductor base material 111 by, for example, spin coating. In the present embodiment, the resin material to be applied has photosensitivity. The organic insulating film 114 to be formed may be, for example, a polyimide film having a glass transition point (Tg) of about 250° C. and a thickness of about 5 μm. In addition, the organic insulating film 114 may be formed such that the electrode 13 protrudes out from the organic insulating film 114 by 60 to 80 nm. The organic insulating film 114 has a plurality of portions that become the organic insulating film 14 of the integrated circuit element 10 after the step of cutting the multilayer body 100.

[Step (b)]

Step (b) is a step of pre-baking and semi-curing the organic insulating film 114. In step (b), the organic insulating film 114 is semi-cured by heating the resin material spread on the semiconductor base material 111 at, for example, a temperature of 50 to 150° C.

[Step (c)]

Step (c) is a step of removing at least a part of the planned cutting portion 117 corresponding to the planned cutting line L in the organic insulating film 114. As illustrated in FIG. 3, a plurality of planned cutting lines L are set in the multilayer body 100. The planned cutting line L is an imaginary line indicating a place where the multilayer body 100 is to be cut (diced) in the subsequent step (e). The plurality of planned cutting line L are set at a predetermined pitch in a lattice shape. A rectangular portion surrounded by the plurality of planned cutting lines L corresponds to the integrated circuit element 10. That is, the plurality of integrated circuit elements 10 are obtained by cutting and dividing the multilayer body 100 along the planned cutting line L.

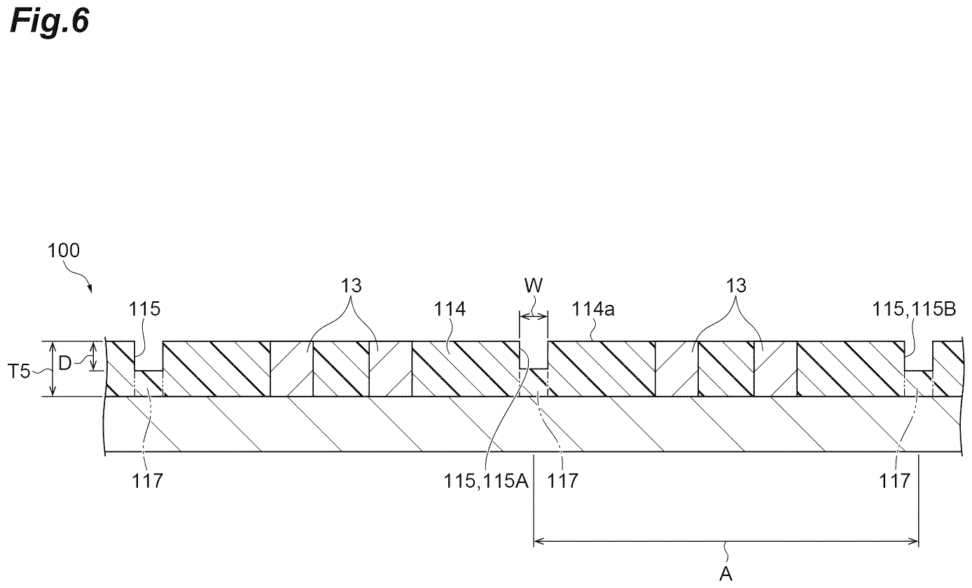

In step (c), as illustrated in FIG. 6, a part of the planned cutting portion 117 corresponding to the planned cutting line L in the organic insulating film 114 is removed, and a groove 115 is formed along the planned cutting line L. Accordingly, the planned cutting portion 117 is thinned. In the present embodiment, the entire planned cutting portion 117 is thinned. That is, when viewed from the thickness direction of the semiconductor base material 111, the removal is performed over the entire planned cutting portion 117. The groove 115 may be formed by, for example, a photolithography process (exposure and development). For example, a negative or positive mask pattern may be formed on the organic insulating film 114, and a part of the planned cutting portion 117 may be removed by performing exposure and development to form the groove 115. Instead of the photolithography process, the groove 115 may be formed by laser ablation, imprinting, or the like.

The groove 115 is formed from the surface 114a of the organic insulating film 114 on the side opposite to the semiconductor base material 111 toward the semiconductor base material 111. The groove 115 is formed in a slit shape. The depth D of the groove 115 with respect to the thickness T5 of the organic insulating film 114 may be, for example, greater than or equal to 5.3%, greater than or equal to 20%, greater than or equal to 40%, or greater than or equal to 60%. The thickness T5 may be, for example, less than or equal to 15 μm. The depth D may be, for example, greater than or equal to 0.8 μm. The aspect ratio of the width W of the groove 115 with respect to the depth D of the groove 115 may be, for example, 15:20 to 0.8:300. That is, width W/depth D may be 1.3 to 375. The width W of the groove 115 may be larger than the cutting margin (dicing width) in the subsequent cutting step (step (e)) of the multilayer body 100. For example, when blade dicing is used in step (e), the width W may be larger than the width of the dicing blade used in blade dicing. The width W of the groove 115 may be, for example, 20 to 300 μm or 20 to 40 μm. The groove 115 includes a plurality of grooves formed at a predetermined pitch in a lattice shape. A pitch A between the grooves (e.g., the groove (first groove) 115A and the groove (second groove) 115B illustrated in FIG. 6) adjacent to each other is, for example, less than or equal to 40 mm.

[Step (d)]

Step (d) is a step of curing the organic insulating film 114 (Cure step). In the present embodiment, the organic insulating film 114 is heated to be cured. The heating temperature may be, for example, 150 to 375° C. The heating temperature in the step (d) may be higher than the heating temperature for when semi-curing the organic insulating film 114 in step (b). After the organic insulating film 114 is cured, the plurality of electrodes 13 and the organic insulating film 114 are polished through chemical mechanical polishing method (CMP method).

[Step (e)]

Step (e) is a step of cutting the multilayer body 100 along the planned cutting line L to acquire the integrated circuit element 10. That is, in step (e), the multilayer body 100 is cut along the groove 115 formed in the organic insulating film 114 to acquire the integrated circuit element 10. In the present embodiment, the multilayer body 100 is cut by blade dicing. At this time, dicing may be performed while performing two-fluid cleaning. The two-fluid cleaning method is a cleaning method performed using a mixed cleaning fluid in which a compressed gas (e.g., clean air) is mixed with a liquid (e.g., pure water) to form a mist. In the two-fluid cleaning method, a higher cleaning ability can be realized by hitting minute liquid (minute liquid particles) against an object at a high speed, while impact applied to the object can be reduced since high-pressure cleaning water is unnecessary. Since the impact is reduced, it is also reduced that the object is damaged or the like and becomes a cause of debris.

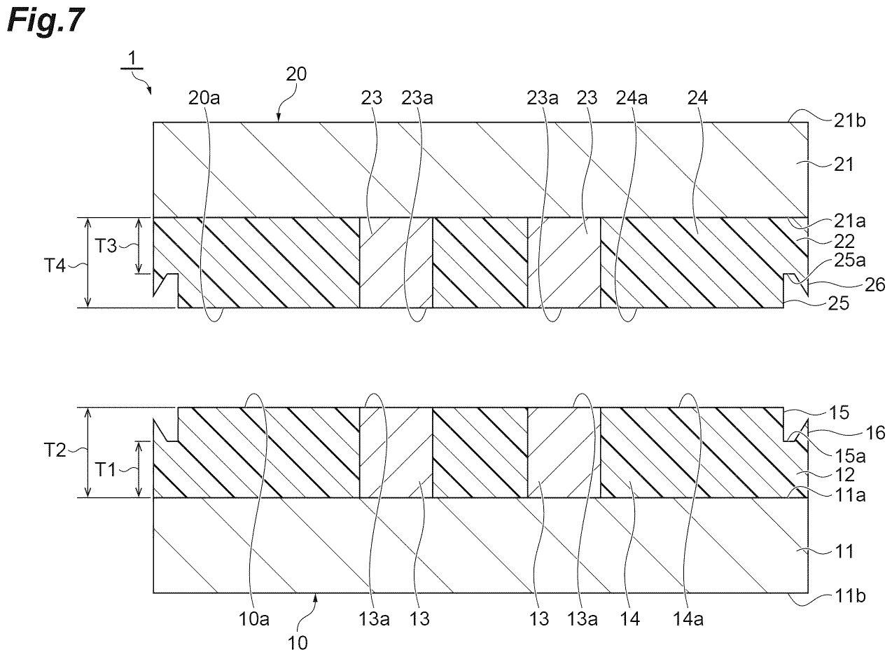

As a method of cutting the multilayer body 100, for example, plasma dicing, stealth dicing, or laser dicing can be used instead of blade dicing. The width of the dicing blade used in blade dicing may be, for example, about 50 μm. The groove 115 formed in the multilayer body 100 constitutes a recess 15 in the integrated circuit element 10 after the cutting, as illustrated in FIG. 7. When the multilayer body 100 is cut, the burr 16 may be formed at the end portion of the organic insulating film 14 depending on the cutting method. For example, when blade dicing is used, the burr 16 may be generated. In the example of FIG. 7, when the integrated circuit element 10 is viewed from a direction perpendicular to the thickness direction of the semiconductor substrate 11, the burr 16 is located in the recess 50 and does not protrude out from the bonding surface 10a (the surface 14a of the organic insulating film 14).

[Step (f)]

Step (f) is a step of bonding the integrated circuit element 10 and the integrated circuit element 20. The integrated circuit element 20 is acquired by a method similar to the method for producing the integrated circuit element 10 described above. In step (f), after organic substances and the like adhered to the surfaces of the bonding surface 10a of the integrated circuit element 10 and the bonding surface 20a of the integrated circuit element 20 are removed, as illustrated in FIG. 7, the bonding surface 10a and the bonding surface 20a are brought to face each other, and the electrode 13 of the integrated circuit element 10 and the electrode 23 of the integrated circuit element 20 are aligned. When the alignment is completed, the organic insulating film 14 of the integrated circuit element 10 and the organic insulating film 24 of the integrated circuit element 20 are bonded. At this time, the organic insulating film 14 and the organic insulating film 24 may be bonded by thermocompression bonding. The heating temperature at the time of bonding the organic insulating film 14 and the organic insulating film 24 may be, for example, higher than or equal to about 250° C.

Thereafter, predetermined heat or pressure, or both, is applied to bond the electrode 13 of the integrated circuit element 10 and the electrode 23 of the integrated circuit element 20. By this bonding process, the electrode 13 and the electrode 23 corresponding thereto are bonded, and the electrode 13 and the electrode 23 are mechanically and electrically bonded. The bonding between the electrode 13 and the electrode 23 is performed after the bonding between the organic insulating film 14 and the organic insulating film 24 as an example, but may be performed simultaneously with the bonding between the organic insulating film 14 and the organic insulating film 24. When the bonding between the integrated circuit element 10 and the integrated circuit element 20 in step (f) is completed, the semiconductor device 1 can be obtained.

As described above, in the method for producing the semiconductor device 1 according to the present embodiment, before the step of curing the organic insulating film 114, a part of the planned cutting portion 117 corresponding to the planned cutting line L in the organic insulating film 114 is removed. In this case, since the volume of the organic insulating film 114 is reduced by removing a part of the planned cutting portion 117, it is possible to reduce warpage of the multilayer body 100 due to curing shrinkage that occurs when the organic insulating film 114 is cured. Therefore, warpage of the integrated circuit element 10 acquired by cutting the multilayer body 100 can be reduced. Furthermore, the planned cutting portion 117 is located at an end portion of the cut and divided integrated circuit element 10. Therefore, even when, for example, the recess 15 is formed at the end portion of the integrated circuit element 10 by removing the planned cutting portion 117, the influence on the bonding between the integrated circuit elements 10 and 20 can be suppressed small as compared with the case where the recess 15 is formed at, for example, the center of the integrated circuit element 10. Furthermore, even when the burr 16 is generated at the time of cutting the multilayer body 100, the burr 16 is located in the space (recess 15) generated by removing a part of the planned cutting portion 117, so that the burr 16 can be suppressed from protruding out from the bonding surface 10a of the integrated circuit element 10. Furthermore, since a part of the planned cutting portion 117 is removed in advance, the generation of debris due to cutting (dicing) of the multilayer body 100 can be suppressed. Therefore, according to the method for producing the semiconductor device 1, the occurrence of a bonding failure between the integrated circuit elements 10 and 20 can be suppressed.

Furthermore, in the method for producing the semiconductor device 1 according to the present embodiment, in the step of removing at least a part of the planned cutting portion 117, the groove 115 is formed in the organic insulating film 114 along the planned cutting line L, thereby removing a part of the planned cutting portion 117. As a result, the planned cutting portion 117 can be more reliably removed.

In addition, in the method for producing the semiconductor device 1 according to the present embodiment, the depth D of the groove 115 is greater than or equal to 20% with respect to the thickness of the organic insulating film 114. In this case, the volume of the organic insulating film 114 can be further reduced, and the warpage of the multilayer body 100 due to the curing shrinkage that occurs when the organic insulating film 114 is cured can be further reduced. As a result, the warpage of the integrated circuit element 10 acquired by cutting the multilayer body 100 is reduced, and the occurrence of bonding failure between the integrated circuit elements 10 and 20 can be further suppressed.

Furthermore, in the method for producing the semiconductor device 1 according to the present embodiment, the aspect ratio of the width W with respect to the depth D of the groove 115 is 15:20 to 0.8:300. In this case, the groove 115 having an appropriate size can be formed in the organic insulating film 114.

In the method for producing the semiconductor device 1 according to the present embodiment, the groove 115 includes the groove 115A and the groove 115B adjacent to each other, and the pitch A between the groove 115A and the groove 115B is less than or equal to 40 mm. In this case, since many grooves 115 are formed in the organic insulating film 114, the volume of the organic insulating film 114 can be further reduced, and the warpage of the multilayer body 100 due to the curing shrinkage that occurs when the organic insulating film 114 is cured can be further reduced. As a result, the warpage of the integrated circuit element 10 acquired by cutting the multilayer body 100 is reduced, and the occurrence of bonding failure between the integrated circuit elements 10 and 20 can be further suppressed.

In the method for producing the semiconductor device 1 according to the present embodiment, the resin material has photosensitivity, and in the step of removing at least a part of the planned cutting portion 117, exposure and development are performed on the organic insulating film 114 to remove a part of the planned cutting portion 117. This makes it possible to easily remove a part of the planned cutting portion 117 while maintaining the flatness of the surface 114a of the organic insulating film 114. It is also possible to remove the fine planned cutting portion 117.

Furthermore, the method for producing the semiconductor device 1 according to the present embodiment further includes a step of pre-baking and semi-curing the organic insulating film 114 before the step of removing at least a part of the planned cutting portion 117. As a result, in a state where the organic insulating film 114 is semi-cured, removal of a part of the planned cutting portion 117 (e.g., formation of the groove 115) can be accurately carried out.

Furthermore, in the method for producing the semiconductor device 1 according to the present embodiment, in the step of removing at least a part of the planned cutting portion 117, the entire planned cutting portion 117 is thinned. As a result, the volume of the organic insulating film 114 can be further reduced, and the warpage of the multilayer body 100 due to the curing shrinkage that occurs when the organic insulating film 114 is cured can be further reduced. As a result, the warpage of the integrated circuit element 10 acquired by cutting the multilayer body 100 is reduced, and the occurrence of bonding failure between the integrated circuit elements 10 and 20 can be further suppressed.

Furthermore, in the method for producing the semiconductor device 1 according to the present embodiment, in the step of acquiring the integrated circuit element 10, the multilayer body 100 is cut with a dicing blade. Although the burr 16 may be generated when the multilayer body 100 is cut by the dicing blade, the burr 16 can be suppressed from protruding out from the bonding surface 10a of the integrated circuit element 10 for the reason described above. Therefore, the occurrence of a bonding failure between the integrated circuit elements 10 and 20 can be suppressed.

In the semiconductor device 1, the thickness T1 of the outer edge portion of the organic insulating film 14 included in the integrated circuit element 10 is thinner than the thickness T2 of the other portion of the organic insulating film 14. In this case, in the process of producing the semiconductor device 1, the volume of the organic insulating film 114 to be the organic insulating film 14 can be reduced, and the multilayer body 100 including the organic insulating film 114 can be suppressed from being warped due to curing shrinkage when the organic insulating film 114 is cured. This can reduce the warpage of the integrated circuit element 10. In addition, in the semiconductor device 1, a portion where the thickness of the organic insulating film 14 is thin is an end portion of the integrated circuit element 10. Therefore, it is possible to suppress the influence on the bonding between the integrated circuit elements 10 and 20 due to the thin thickness of the organic insulating film 14. Furthermore, in the semiconductor device 1, even when the burr 16 is generated in the outer edge portion of the organic insulating film 14, the burr 16 can be suppressed from protruding out from the bonding surface 10a of the integrated circuit element 10. Therefore, according to the semiconductor device 1, the occurrence of a bonding failure between the integrated circuit elements 10 and 20 can be suppressed.

### EXAMPLES

Hereinafter, the present invention will be described more specifically with reference to the examples. However, the present invention is not limited to the following examples.

### (Measurement of Warpage of Multilayer Body)

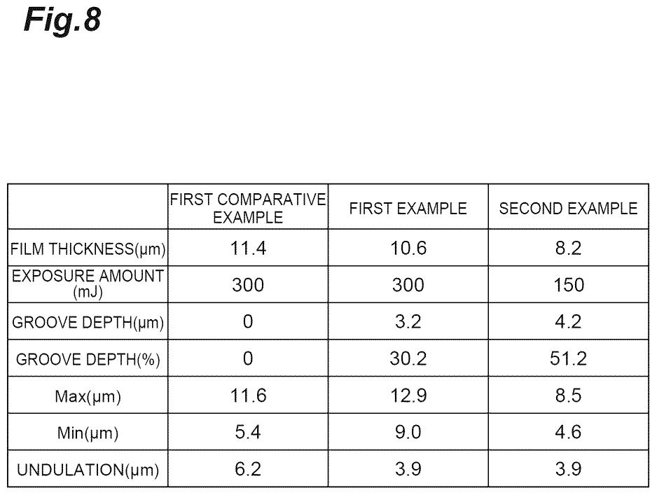

Multilayered bodies according to a first comparative example and first and second examples were formed, and warpage generated in each multilayer body was measured. As illustrated in FIG. 8, in this measurement, three multilayer bodies were prepared as the first comparative example and first and second examples. Unlike the multilayer body 100 of the above-described embodiment, the groove 115 was not formed in the multilayer body according to the first comparative example. The multilayered bodies according to the first and second examples had the same configuration as the multilayer body 100 of the above-described embodiment, and the groove 115 was formed.

The “film thickness (μm)” in FIG. 8 indicates the thickness of the organic insulating film of each multilayer body. In the present example, a groove (corresponding to the groove 115) was formed in the organic insulating film having the film thickness illustrated in FIG. 8 by a photolithography process (exposure and development). “Exposure amount (mJ)” in FIG. 8 indicates the exposure amount at that time. The “groove depth (μm)” in FIG. 8 indicates the depth of the groove formed in the organic insulating film. The groove depth (μm) corresponds to the depth D illustrated in FIG. 6. The “groove depth (%)” in FIG. 8 is a ratio of the groove depth (μm) with respect to the film thickness (μm), and is calculated by dividing the film thickness (μm) by the groove depth (μm) and multiplying the result by 100. The groove depth (%) in the first example was 30.2%, and the groove depth (%) in the second example was 51.2%. In the first and second examples, the width of the groove was 245 μm. Furthermore, the aspect ratio of the width with respect to the depth of the groove in the first example was 3.2:245, and the aspect ratio in the second example was 4.2:245. That is, the width of the groove/the depth of the groove in the first example was 76.6, and the width of the groove/the depth of the groove in the second example was 58.4. The pitch between adjacent grooves was 7.15 mm.

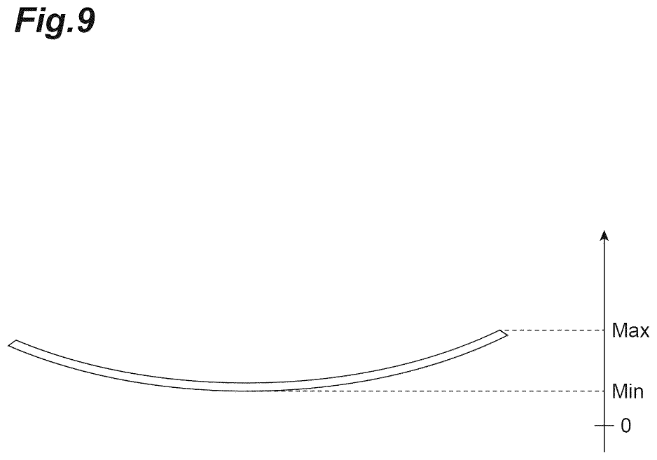

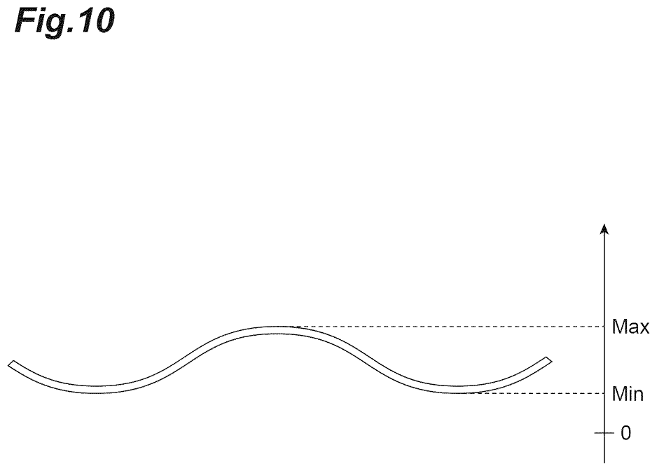

After the groove was formed, the organic insulating film was cured by heating, and warpage of the multilayer body due to curing shrinkage was measured. “Max (μm)” in FIG. 8 indicates a distance between a reference surface and a portion farthest from the reference surface in the multilayer body after the occurrence of warpage in a case where the reference surface parallel to the flat multilayer body before the occurrence of warpage is assumed. For example, in a multilayer body in which warpage has occurred as illustrated in FIG. 9, when the position of the reference surface is “0”, the position of the end portion of the multilayer body is Max. On the other hand, in a multilayer body in which warpage has occurred as illustrated in FIG. 10, when the position of the reference surface is “0”, the position of the vertex of the central convex portion in the multilayer body is Max. “Min (μm)” in FIG. 8 indicates a distance between a reference surface and a portion closest to the reference surface in the multilayer body after the occurrence of warpage in a case where the reference surface parallel to the flat multilayer body before the occurrence of warpage is assumed. For example, in a multilayer body in which warpage has occurred as illustrated in FIG. 9, when the position of the reference surface is “0”, the position of the vertex of the convex portion in the multilayer body is Min. On the other hand, in a multilayer body in which warpage has occurred as illustrated in FIG. 10, when the position of the reference surface is “0”, the position of the vertex of the convex portion on the end portion side in the multilayer body is Min.

“Undulation (μm)” in FIG. 8 indicates the degree of warpage of the multilayer body, and is calculated by subtracting Min (μm) from Max (μm). As illustrated in FIG. 8, the undulation of the multilayered bodies according to the first and second examples in which the groove was formed in the organic insulating film is smaller than the undulation of the multilayer body according to the first comparative example in which the groove was not formed. As described above, it has been confirmed that at least a part of the organic insulating film is removed before curing due to formation of a groove or the like in the organic insulating film, whereby the warpage of the multilayer body when the organic insulating film is cured can be reduced.

### (Observation of Burr)

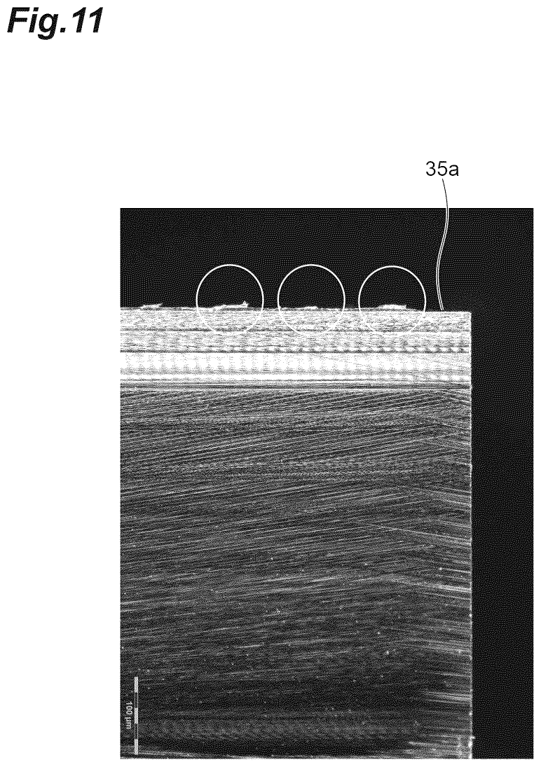

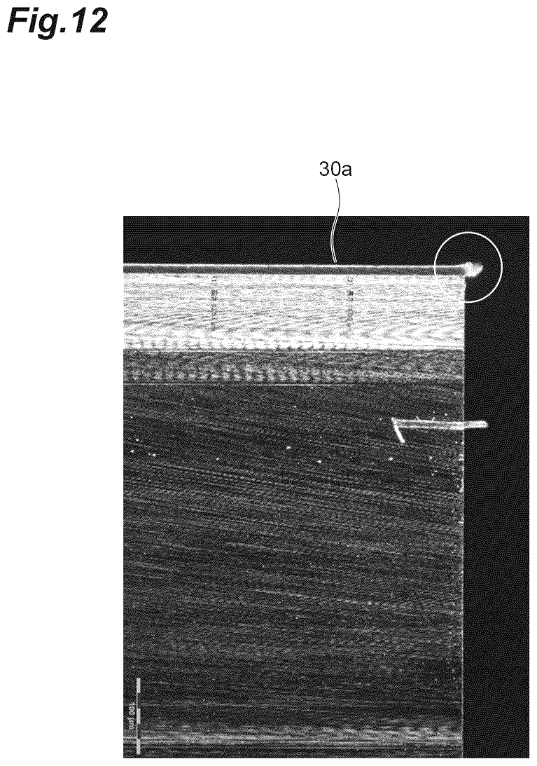

The integrated circuit elements according to a second comparative example and a third example were formed, and the burrs formed in the integrated circuit elements were observed. FIG. 11 is a photograph of a burr formed in an integrated circuit element according to the third example, and FIG. 12 is a photograph of a burr formed in an integrated circuit element according to the second comparative example. In the integrated circuit element according to the second comparative example, unlike the integrated circuit element 10 of the above-described embodiment, the recess 15 was not formed. The integrated circuit element according to the third example had the same configuration as the integrated circuit element 10 of the above-described embodiment, and the recess 15 was formed.

FIGS. 11 and 12 are photographs of the integrated circuit element taken from a direction perpendicular to the thickness direction of the semiconductor substrate included in the integrated circuit element. In FIGS. 11 and 12, white protrusions surrounded by circles are burrs. In FIG. 11, the background of the burr is black, but actually, the surface of the organic insulating film constituting the recess exists on the far side of the burr. In the integrated circuit element of the third example illustrated in FIG. 11, the burr was formed on the bottom surface of the recess (the surface indicated by reference numeral 35a in FIG. 11), was located in the recess, and did not protrude out from the bonding surface of the integrated circuit element. On the other hand, in the second comparative example illustrated in FIG. 12, the burr protruded out from the bonding surface (surface indicated by reference numeral 30a in FIG. 12) of the integrated circuit element. As described above, it was confirmed that the protrusion of the burr from the bonding surface of the integrated circuit element was suppressed by the formation of the recess.

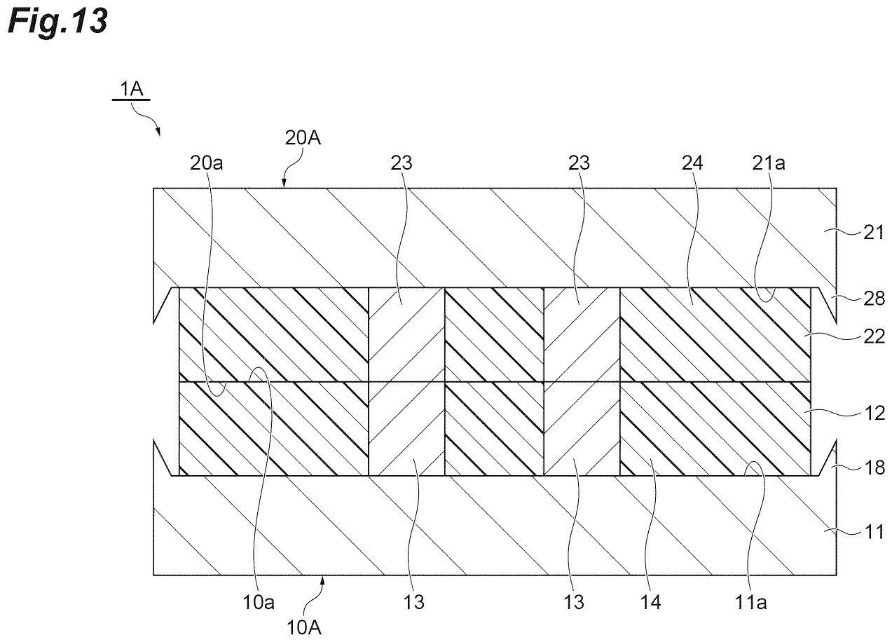

Although the embodiments of the present disclosure have been described in detail above, the present invention is not limited to the above-described embodiments. The semiconductor device 1 may be configured as, for example, a semiconductor device 1A according to a modified example illustrated in FIG. 13. FIG. 13 is a cross-sectional view schematically illustrating a semiconductor device according to a modified example. The semiconductor device 1A includes an integrated circuit element 10A and an integrated circuit element 20. In the integrated circuit element 10A, unlike the integrated circuit element 10 described above, the organic insulating film 14 is not disposed on the outer edge portion of the semiconductor substrate 11. That is, when viewed from the thickness direction of the semiconductor substrate 11, the outer edge of the organic insulating film 14 is located on the inner side of the outer edge of the semiconductor substrate 11. An outer edge portion of the main surface 11a of the semiconductor substrate 11 is exposed from the organic insulating film 14. A burr 18 is formed in the outer edge portion of the main surface 11a. In the example of FIG. 13, the burr 18 does not protrude out from the bonding surface 10a of the integrated circuit element 10A.

The integrated circuit element 10A is formed by removing the planned cutting portion 117 until the semiconductor base material 111 is exposed in step (c) of the method for producing the semiconductor device 1 described above. In other words, the semiconductor base material 111 can be exposed by forming the groove 115 having the depth D equal to the thickness T5 of the organic insulating film 114. In the present modified example, when the multilayer body 100 is cut along the planned cutting line L, only the semiconductor base material 111 is cut since the organic insulating film 114 does not exist on the planned cutting line L. As a result, in the cut and divided integrated circuit element 10A, the burr 18 is formed in the outer edge portion of the semiconductor substrate 11.

An integrated circuit element 20A according to the present modified example has the same configuration as the integrated circuit element 10A, and can be produced by the same production steps as those of the integrated circuit element 10A. In the semiconductor device 1A, the wiring layer 12 of the integrated circuit element 10A and the wiring layer 22 of the integrated circuit element 20A are bonded to each other via the bonding surface 10a and the bonding surface 20a. The burr 18 formed in the semiconductor substrate 11 of the integrated circuit element 10A and the burr 28 formed in the semiconductor substrate 21 of the integrated circuit element 20A are not in contact with each other.

Similarly to the semiconductor device 1 according to the above-described embodiment, with the semiconductor device 1A according to the present modified example as well, the occurrence of a bonding failure between integrated circuit elements can be suppressed. In particular, in the present modified example, in the production step of the semiconductor device 1A, the planned cutting portion 117 is removed until the semiconductor base material 111 is exposed. Therefore, the volume of the organic insulating film 114 can be further reduced as compared with the above-described embodiment. Therefore, it is advantageous in that warpage of the multilayer body 100 due to curing shrinkage when the organic insulating film 114 is cured can be further reduced.

The present disclosure is not limited to the above-described embodiments and modified examples. For example, in the step of removing at least a part of the planned cutting portion 117, the removal may not be performed over the entire planned cutting portion 117 when viewed from the thickness direction of the semiconductor base material 111. That is, when viewed from the thickness direction of the semiconductor base material 111, a part of the planned cutting portion 117 may be removed. For example, the planned cutting portion 117 may be partially removed such that the removed portion is discontinuous. Specifically, a plurality of recesses (grooves) or through holes may be formed in the planned cutting portion 117. Furthermore, the removal may be performed only on the planned cutting portion 117 corresponding to some planned cutting lines L among the plurality of planned cutting lines L.

In the above-described embodiments and modified examples, the case where the present invention is applied to the hybrid bonding in C2C (Chip to Chip) has been exemplified, but the present invention may be applied to C2W (Chip to Wafer).

### REFERENCE SIGNS LIST

1, 1A semiconductor device
10, 10A, 20, 20A integrated circuit element
11, 21 semiconductor substrate
11a, 21a, 111a main surface
13, 23 electrode
14 organic insulating film
16, 18, 26, 28 burr
24 organic insulating film
100 multilayer body
111 semiconductor base material
114 organic insulating film
115, 115A, 115B groove
117 planned cutting portion
L planned cutting line

1. A method for producing a semiconductor device comprising:
preparing a multilayer body including a semiconductor base material, an electrode disposed on a main surface of the semiconductor base material, and an organic insulating film disposed on the main surface and containing a resin material that exhibits curability;
curing the organic insulating film;
cutting the multilayer body along a planned cutting line to acquire at least one integrated circuit element; and
bonding the acquired integrated circuit element to another integrated circuit element,
wherein the method further comprises:
removing at least a part of a planned cutting portion corresponding to the planned cutting line in the organic insulating film before the curing the organic insulating film.

2. The method for producing the semiconductor device according to claim 1, wherein the removing at least a part of the planned cutting portion includes forming a groove in the organic insulating film along the planned cutting line.

3. The method for producing the semiconductor device according to claim 2, wherein a depth of the groove is greater than or equal to 20% with respect to a thickness of the organic insulating film.

4. The method for producing the semiconductor device according to claim 2, wherein an aspect ratio of a width with respect to a depth of the groove is 15:20 to 0.8:300.

5. The method for producing the semiconductor device according to claim 2, wherein
the groove includes a first groove and a second groove adjacent to each other, and
a pitch between the first groove and the second groove is less than or equal to 40 mm.

6. The method for producing the semiconductor device according to claim 1, wherein the resin material has photosensitivity, and
at least a part of the planned cutting portion is removed by performing exposure and development on the organic insulating film.

7. The method for producing the semiconductor device according to claim 1, further comprising pre-baking and semi-curing the organic insulating film before the removing at least a part of the planned cutting portion.

8. The method for producing the semiconductor device according to claim 1, wherein the removing at least a part of the planned cutting portion includes thinning or removing the entire planned cutting portion.

9. The method for producing the semiconductor device according to claim 1, wherein the acquiring the integrated circuit element includes cutting the multilayer body with a dicing blade.

10. A semiconductor device comprising:
an integrated circuit element; and
another integrated circuit element bonded to the integrated circuit element, wherein
the integrated circuit element includes a semiconductor substrate, and an electrode and an organic insulating film disposed on a main surface of the semiconductor substrate, and
a thickness of an outer edge portion of the organic insulating film is thinner than a thickness of another portion of the organic insulating film, or the organic insulating film is not disposed on an outer edge portion of the semiconductor substrate.

11. The semiconductor device according to claim 10, wherein a burr is formed in the outer edge portion of the organic insulating film or the outer edge portion of the semiconductor substrate.

12. A method for producing an integrated circuit element comprising:
preparing a multilayer body including a semiconductor base material, an electrode disposed on a main surface of the semiconductor base material, and an organic insulating film disposed on the main surface and containing a resin material that exhibits curability; curing the organic insulating film; and
cutting the multilayer body along a planned cutting line to acquire at least one integrated circuit element, wherein the method further comprises:
removing at least a part of a planned cutting portion corresponding to the planned cutting line in the organic insulating film before the curing the organic insulating film.

13. An integrated circuit element comprising:
a semiconductor substrate; and
an electrode and an organic insulating film disposed on a main surface of the semiconductor substrate, wherein
a thickness of an outer edge portion of the organic insulating film is thinner than a thickness of another portion of the organic insulating film, or the organic insulating film is not disposed on an outer edge portion of the semiconductor substrate.
